(19) United States
(12) Patent Application Publication
(10) Pub. No.: US 2008/0302564 A1
(43) Pub. Date: Dec. 11, 2008

(54) CIRCUIT ASSEMBLY INCLUDING A METAL CORE SUBSTRATE AND PROCESS FOR PREPARING THE SAME

(75) Inventors: Kevin C. Olson, Wexford, PA (US); Thomas W. Goodman, Tempe, AZ (US); Peter Elenius, Scottsdale, AZ (US)

Correspondence Address: PPG INDUSTRIES INC;INTELLECTUAL PROPERTY DEPT, ONE PPG PLACE, PITTSBURGH, PA, 15272, US

(73) Assignee: PPG INDUSTRIES OHIO, INC., Cleveland, OH (US)

(21) Appl. No.: 11/760,887

(22) Filed: Jun. 11, 2007

(51) Int. Cl. H05K 1/05; H05K 3/10

(52) U.S. Cl. 174/268; 29/846

(57) ABSTRACT

A substrate for an electronic device package includes an electrically conductive core shaped to define a cavity for receiving an electronic device, a first insulating layer positioned on a first side of the core, and a first contact positioned adjacent to a surface within the cavity. Method of fabricating the substrates is also provided.

### FIELD OF THE INVENTION

The present invention relates to electronic circuit assemblies, and more particularly, to circuit assemblies including semiconductor devices, and the preparation thereof.

### BACKGROUND OF THE INVENTION

Microelectronic circuit packages are prepared in various sizes. One packaging level includes semiconductor chips containing multiple microcircuits and/or other components. Such chips are usually made from semiconductors such as silicon, and the like. Intermediate package levels (i.e., “chip carriers”) comprising multi-layer substrates may include a plurality of chips. Likewise, these intermediate package levels can be attached to larger scale circuit cards, motherboards, and the like. The intermediate package levels serve several purposes in the overall circuit assembly including structural support, transitional integration of the smaller scale circuits to larger scale boards, and the dissipation of heat from the circuit components. Substrates used in conventional intermediate package levels have included a variety of materials, for example, ceramics, fiberglass reinforced polyepoxides, and polyimides.

The aforementioned substrates, while offering sufficient rigidity to provide structural support to the circuit assembly, typically have thermal coefficients of expansion much different than that of the microelectronic chips attached to them. As a result, failure of the circuit assembly after repeated use is a risk due to the failure of joints between the layers of the assembly.

Likewise, dielectric materials used on the substrates must meet several requirements, including conformality, flame resistance, and compatible thermal expansion properties. Conventional dielectric materials include, for example, polyimides, polyepoxides, phenolics, and fluorocarbons. These polymeric dielectrics typically have thermal coefficients of expansion much higher than that of the adjacent layers.

With ever increasing efforts to miniaturize microelectronics, the areas and thicknesses occupied by chips and other devices on packaging substrates has become smaller and thinner.

It would be desirable to provide a circuit assembly with improved thermal and structural properties that overcome the drawbacks of the prior art.

### SUMMARY OF THE INVENTION

In a first aspect, the invention provides a substrate for an electronic device package comprising an electrically conductive core shaped to define a cavity for receiving an electronic device, a first insulating layer positioned on a first side of the core, and a first contact positioned adjacent to a surface within the cavity.

In another aspect, the invention provides a method of making a substrate for an electronic device package comprising: providing an electrically conductive core, deforming the core to define a cavity for receiving an electronic device, applying a first insulating layer to a first side of the core, and forming a first contact adjacent to a surface within the cavity.

### BRIEF DESCRIPTION OF THE DRAWINGS

FIG. 1 is a plan view of a circuit assembly constructed in accordance with an embodiment of the invention.

FIG. 2 is a cross-sectional view of the circuit assembly of FIG. 1 taken along line 2-2.

FIG. 3 is a cross-sectional view of the circuit assembly of FIG. 1 taken along line 3-3.

FIG. 4 is a plan view of another circuit assembly constructed in accordance with an embodiment of the invention.

FIG. 5 is a cross-sectional view of the circuit assembly of FIG. 4 taken along line 5-5.

FIG. 6 is a cross-sectional view of the circuit assembly of FIG. 4 taken along line 6-6.

FIGS. 7, 8 and 9 are cross-sectional views of other circuit assemblies constructed in accordance with several embodiments of the invention.

FIG. 10 is a plan view of a substrate constructed in accordance with an embodiment of the invention.

FIG. 11 is a cross-sectional view of the substrate of FIG. 7 taken along line 11-11.

FIG. 12 is a cross-sectional view of the circuit assembly according to another aspect of the invention.

### DETAILED DESCRIPTION OF THE INVENTION

In one aspect, this invention provides a circuit assembly that includes a semiconductor device mounted on a substrate, wherein the substrate includes a conductive core and a first layer of insulating material on a first side of the conductive core. The substrate is shaped to form a cavity, and at least a portion of the semiconductor device is positioned in the cavity. First and second conductors are provided in the cavity. The first conductor electrically connects a first contact of the semiconductor device to the core, and the second conductor is electrically connected to a second contact of the semiconductor device and extends from the second contact to an edge of the cavity. The assembly is mechanically robust and provides for efficient removal of heat from the semiconductor device.

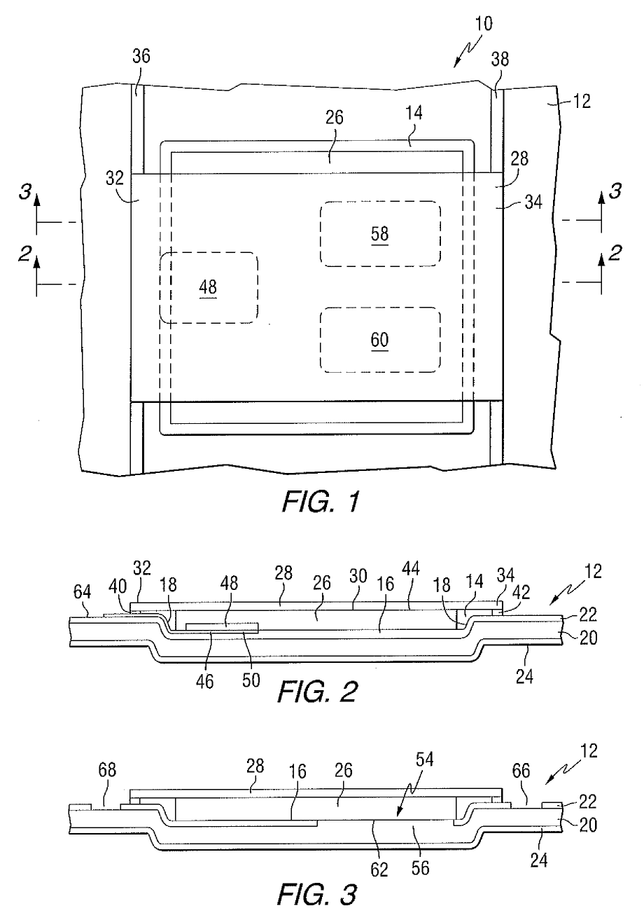

Referring to the drawings, FIG. 1 is a plan view and FIGS. 2 and 3 are cross-sectional views of a circuit assembly 10 constructed in accordance with one embodiment of the invention. The circuit assembly includes a substrate 12 having a core 20 shaped to form a cavity 14 having a bottom 16 and sides 18 that extend from the periphery of the bottom. First and second layers 22 and 24 of an insulating material are positioned on opposite sides (or surfaces) of the core. The core 20 can be a single layer, or multi-layer structure. The cavity is shaped to receive a semiconductor device 26 (also referred to as a chip). In one example, the semiconductor device is a metal oxide semiconductor field effect transistor (MOSFET). An electrically conductive member (or contact) 28 is positioned adjacent to, and in electrical contact with a top surface 30 of the semiconductor device. The ends 32 and 34 of the electrically conductive member 28 are electrically connected to conductors 36 and 38 on the substrate. The electrical connection between the ends 32 and 34 of the electrically conductive member 28 and the conductors 36 and 38 can be implemented using solder joints 40 and 42. Similarly, the electrically conductive member 28 can be electrically connected to the top of the semiconductor device using a solder joint 44.

One or more electrical conductors or contacts, also referred to as connection pads, are positioned adjacent to a surface (e.g., a bottom or sidewall surface) in the cavity. In this example, connection pad 46 is positioned on the first layer of insulating material 22 and is electrically connected to a contact 48 on the semiconductor device. The pad 46 extends from the contact 48 to an edge of the cavity, and possibly beyond the edge, and is electrically insulated from the core by the first layer of insulating material. The connection between pad 46 and contact 48 can be made using a solder joint 50. In one example, the contact can be a gate contact of a MOSFET. The connection pad 46 provides a means for connecting another device or circuit board to the semiconductor device.

One or more openings, or blind vias, 54 can be formed in the first layer of insulating material 22. These vias can be filled with an electrically conductive material 56 to form conductors that electrically connect contacts 58 and 60 on the semiconductor device to the core of the substrate. The electrically conductive material 56 can be connected to the contacts 58 and 60 using solder joints 62. In one example, the contacts 58 and 60 can be source contacts of a MOSFET. An opening 66 is provided in the insulating coating to create a blind via that can be used to make an electrical connection to the core.

While FIG. 1 illustrates a circuit assembly including a semiconductor device in the form of a MOSFET, it should be understood that the invention is not limited to any particular type of electronic device or circuit. For example, the MOSFET of FIG. 1 could be replaced by another type of electronic device, a logic circuit, a power amplifier, etc.

By mounting the electronic device within the cavity, electrical and/or thermal connections can be made to the top of the semiconductor device using connectors that lie substantially in the plane of a top surface 64 of the substrate. In addition, thermal connections can be made to both the top and bottom surfaces of the device, and electrical connections can be made to the back of the device. This construction also provides embedded interconnectivity. Signal propagation can be improved with low-loss copper connections. The electronic device can be mounted close to passive devices for improved decoupling. The assembly has a reduced form factor compared to previous assemblies. Distance between electrical traces/lines can be shortened.

In addition, the compact structure provides improved thermal properties to efficiently remove heat from the semiconductor device. By positioning the device in the cavity, the backside of the device can be in the same plane as the connection pads on the top surface of the package, thereby providing a single soldering plane to facilitate manufacturing of the assembly.

The substrate core layer can comprise any of a variety of materials, such as a metal, which may be for example, untreated or galvanized steel, aluminum, gold, nickel, copper, magnesium or alloys of any of the foregoing metals, as well as conductive carbon coated materials or metalized non-conductive materials such as sputtered ceramic or coated plastic. More particularly, the substrate can comprise a metal core selected from copper foil, nickel-iron alloys, and combinations or multiple layers thereof. The substrate can also be a perforate substrate comprised of any of the previously mentioned metals or combinations thereof.

In some embodiments, the substrate comprises a nickel-iron alloy, such as INVAR, (trademark owned by Imphy S. A., 168 Rue de Rivoli, Paris, France) comprising approximately 64 weight percent iron and 36 weight percent nickel. This alloy has a low coefficient of thermal expansion, comparable to that of the silicon materials used to prepare chips. This property is desirable in order to prevent failure of adhesive joints between successively larger or smaller scale layers of a chip scale package, due to thermal cycling in storage or normal use. When a nickel-iron alloy is used as the electrically conductive core, a layer of copper metal can be applied to all surfaces of the electrically conductive core to provide increased conductivity. The layer of copper metal may be applied by conventional means, such as electroplating or metal vapor deposition. The layer of copper typically can have a thickness of from 1 to 10 microns.

In the example of FIGS. 1, 2 and 3, the semiconductor device is a MOSFET mounted in the cavity of the substrate. The MOSFET includes a gate contact, a drain contact, and two source contacts. The gate contact 48 can be electrically connected, for example by soldering, to the first pad, or electrical conductor 46. The source contacts 58 and 60 can be electrically connected, for example by soldering, to the core through the conductive material in the via 54. The drain contact on top of the MOSFET can be electrically connected, for example by soldering, to the conductive member 28.

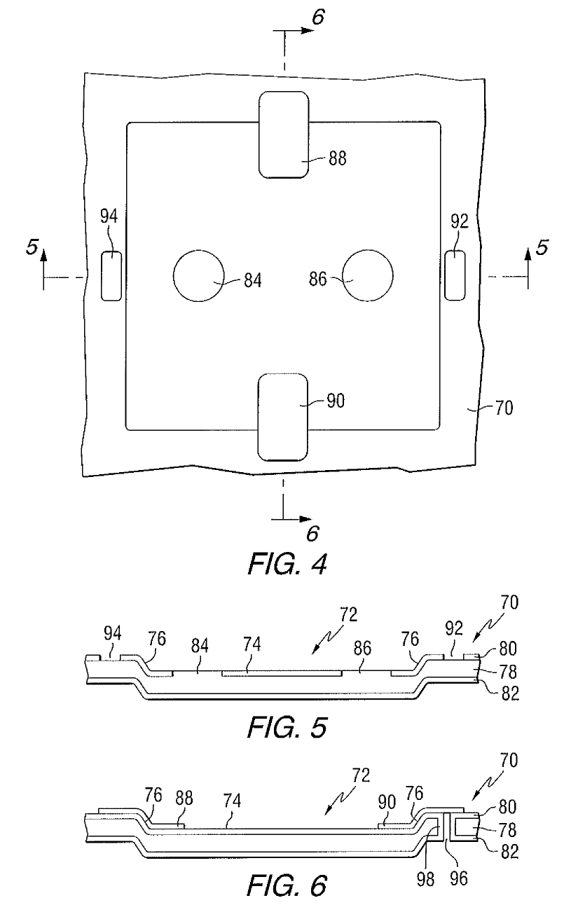

FIG. 4 is a plan view and FIGS. 5 and 6 are cross-sectional views of an alternative embodiment of a substrate 70 including a core 78 shaped to form a cavity 72 having a bottom 74 and sides 76 that extend from the periphery of the bottom. First and second layers 80 and 82 of an insulating material are positioned on opposite sides of the core. The substrate can include a plurality of electrical conductors or contact pads, illustrated as items 84, 86, 88 and 90. The contact pads (for example 88 and 90) can be mounted on a surface of, or embedded in, the first layer of insulating material, or in vias to form contact pads (for example 84 and 86) that are electrically connected to the core layer of the substrate. The arrangement of the contact pads can be chosen to accommodate various semiconductor devices mounted at least partially in the cavity. In the example of FIG. 4, pads 88 and 90 extend to the edges of the cavity, and possibly beyond the edges of the cavity, and provide a means for connecting a device mounted in the cavity to another circuit. Opening 92 and 94 in the top layer of insulation form blind vias that expose portions of the core and can include conductive material used to make electrical connections to the core. One or more vias 96 can be provided in the substrate. Such vias can extend through the core and can be insulated, for example by a layer of dielectric material 100, from the core. The vias can be filled with a conductive material, or one or more conductors can pass through the vias, to provide an electrical connection between components or circuits positioned on opposite sides of the core.

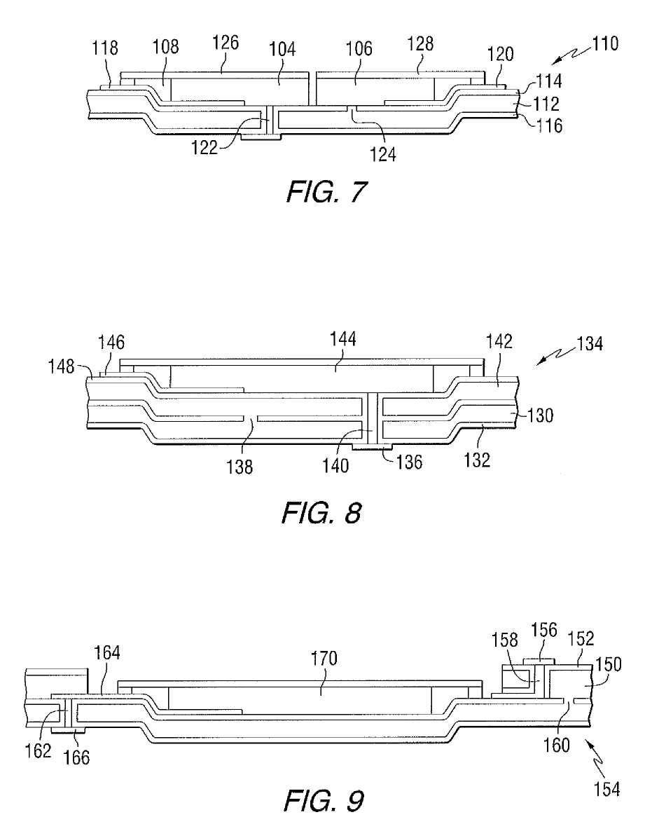

FIGS. 7, 8 and 9 are cross-sectional views of other circuit assemblies constructed in accordance with an embodiment of the invention. FIG. 7 illustrates an embodiment wherein a plurality of electronic devices 104 and 106 are located in a cavity 108 of a substrate 110. Again, the substrate includes a conductive core 112 and first and second layers of insulation 114 and 116, positioned on opposite sides of the core. One or more conductors, such as conductors 118 and 120, which are insulated from the core, can be positioned in the cavity and can extend to the edge of the cavity and beyond to provide a means for electrically connecting the electronic devices to a circuit outside of the cavity. Such circuit can include conductors formed on the layer 114 of insulation. One or more through vias 122, and/or one or more blind vias 124, can be formed in the substrate in the cavity region to provide electrical connections between the electronic devices and the core or circuitry on the other side of the core. Conductors 126 and 128 are provided to make electrical connections to the top sides of the electronic devices 104 and 106. Conductors 126 and 128 are provided to make electrical connections to the top sides of electronic devices 104 and 106.

FIG. 8 illustrates an embodiment wherein an additional core layer 130 and an additional layer of insulating material 132 are built-up on the bottom of a substrate 134. A circuit 136 can be formed on the insulating layer 132, and one or more vias 138 and 140 can optionally be provided to connect cores 130 and 142 to each other, to connect circuitry to one or more of the cores, to connect electronic devices to one or more of the cores, or to connect circuits on opposite sides of the cores. In the embodiment of FIG. 8, an electronic device 144 is connected by a trough via 140 to the circuit 136 on layer 132. Additional conductors 146 can be provided to connect the electronic device to circuitry on layer 148.

FIG. 9 illustrates an embodiment wherein an additional core layer 150 and an insulating layer 152 are built-up on the top of a substrate 154. A circuit 156 can be formed on the insulating layer 152, and one or more vias such as 158 and 160 can be provided to connect various elements to each other. For example, cores 154 and 162 can be connected to each other, circuitry on the layers of insulation can be connected to one or more of the cores, the electronic device can be connected to one or more of the cores, or circuits on opposite sides of the cores can be connected to each other.

In another aspect, the invention encompasses a method of making an electronic circuit assembly. The method comprises: (a) providing an electrically conductive core; (b) deforming the core to form a cavity for receiving at least a portion of a semiconductor device; (c) applying a dielectric coating to a first surface of the electrically conductive core; and (d) forming electrical conductors on a surface of the dielectric coating and in vias in the dielectric coating. In this example, a metal core is formed first, then any necessary pretreatments, dielectric coating application, sputtering, plating patterning, etc. are subsequently applied. The accesses to the core can he created prior to or after metallization and patterning. The dielectric coating can be a conformal coating.

In some embodiments, prior to the application of the dielectric coating, a layer of metal, for example copper, may be applied to the core to ensure optimum electrical conductivity. This layer of metal, as well as that applied in subsequent metallization steps, can be applied by conventional means, for example, by electroplating, metal vapor deposition techniques, or electroless plating. The layer of metal typically can have a thickness of from 1 to 20 microns, and preferably from 5 to 10 microns.

The conductors or contacts can be formed by chemical, mechanical or laser ablating or using masking technologies to prevent coating application at selected areas or otherwise removing portions of the dielectric coating in a predetermined pattern to expose sections of the electrically conductive core, and applying a layer of metal to portions of the dielectric coating to form conductors and contacts. Metallization of at least one of the dielectric coating layers can also be used to form contacts and conductors adjacent to the surface of the dielectric coating layers.

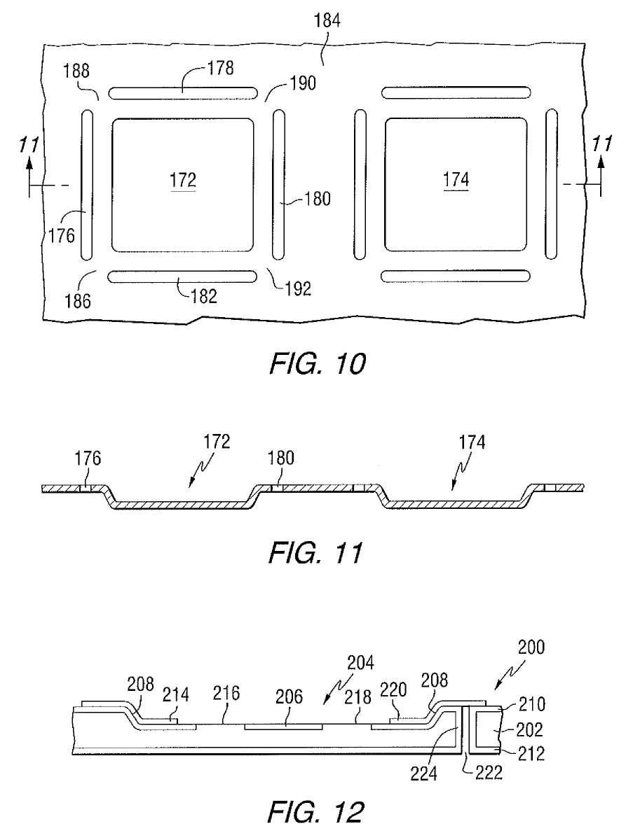

Multiple cavities can be formed in a single large sheet of core material. FIG. 10 is a plan view of a sheet 170 of core material including cavities 172 and 174. FIG. 11 is a cross-sectional view of the substrate of FIG. 10 taken along line 11-11. A plurality of slots or openings, for example 176, 178, 180, 182, are formed adjacent to the portions of the sheet that will form the cavities. The cavities can be formed by stamping or otherwise mechanically deforming or removing a portion of the substrate. The cavities can also be formed using known chemical milling technology. Alternatively, the cavities could be formed by preferentially etching the core in a desired location. In another example any combination of these deformation techniques could be used. The slots aid in the forming/punching process. The slots also define a disposable portion of the sheet 184. The core cavities are connected to the disposable portion by tabs, for example 186, 188, 190 and 192. These tabs can be broken or cut to remove the core cavities from the disposable portion.

In some embodiments, the electrically conductive cores can have a thickness of about 20 to 400 microns, or more specifically 150 to 250 microns. The cores can include a plurality of holes. The holes can have a uniform size and shape. When the holes are circular, the diameter of the holes can be about 8 mil (203.2 microns). The holes may be larger or smaller as necessary, with the provision that the holes are large enough to accommodate all the layers applied in the process of the present invention without becoming obstructed.

The dielectric coating can be applied to the exposed surfaces of the core to form a conformal coating thereon. As used herein, a “conformal” film or coating refers to a film or coating having a substantially uniform thickness, which conforms to the core topography, including the surfaces within (but, preferably, not occluding) holes in the core. The dielectric coating film thickness can be, for example, between 5 and 50 microns. A lower film thickness is desirable for a variety of reasons. For example, a dielectric coating having a low film thickness allows for smaller scale circuitry.

The dielectric coating used in the process of the present invention may be applied by any suitable conformal coating method including, for example, dip coating, vapor deposition, electrodeposition and autophoresis. Examples of dielectric coatings applied by vapor deposition include poly-(para-xylylenes) (encompassing both substituted and unsubstituted poly-(para-xylylene)); silsesquioxanes; and poly-benzocyclobutene. Examples of dielectric coatings applied by electrodeposition include anodic and cathodic acrylic, epoxy, polyester, polyurethane, polyimide or oleoresinous compositions.

The dielectric coating also can be formed by the electrodeposition of any of the electrodepositable photosensitive compositions. For example, the dielectric coating can be applied to the core by electrodeposition of an electrodepositable coating composition comprising a resinous phase dispersed in an aqueous medium, where the resinous phase has a covalently bonded halogen content of at least 1 percent by weight based on total weight of resin solids present in said resinous phase. Examples of electrodepositable dielectric coating compositions and methods related thereto are described in U.S. Pat. No. 6,713,587, which is hereby incorporated by reference.

The electrodepositable coating compositions can be electrophoretically applied to an electrically conductive substrate (or substrate that has been rendered electroconductive as by metallization). The applied voltage for electrodeposition may be varied and can be, for example, as low as 1 volt to as high as several thousand volts, but typically between 50 and 500 volts. The current density can be between 0.5 ampere and 5 amperes per square foot (0.5 to 5 milliamperes per square centimeter) and tends to decrease during electrodeposition indicating the formation of an insulating conformal film on all exposed surfaces of the substrate.

After the coating has been applied by electrodeposition, it can be cured, usually thermally cured at elevated temperatures ranging from 90° to 300° C. for a period of 1 to 40 minutes to form a conformal dielectric coating over all exposed surfaces of the core.

The insulating layers can also be applied using autophoresis, also referred to as chemiphoresis. Generally, autophoresis is a coating process for depositing an organic coating on a metal surface from an acidic aqueous coating composition in a dip tank. The process involves the controlled release of metal ions from the substrate surface due to the low pH of the aqueous composition, thereby destabilizing the polymer dispersed in the aqueous in the immediate vicinity of the substrate to be coated. This causes coagulation of the polymer particles and deposition of the coagulated polymer onto the substrate surface. As the coating thickness increases, the deposition slows, resulting in an overall uniform coating thickness.

After application of the dielectric coating, the dielectric coating can be removed in one or more predetermined locations to expose one or more sections of the substrate surface. The dielectric coating can be removed by a variety of methods, for example by ablation techniques. Such ablation typically is performed using a laser or by other conventional techniques, for example, mechanical drilling and chemical or plasma etching techniques.

Circuitry on the insulating layers can be formed using a metallization process. Metallization typically is performed applying a layer of metal to all surfaces, allowing for the formation of metallized vias through the substrate (i.e., through vias) and/or to, but not through, the core (i.e., blind vias). The metal applied in this metallization step can be any of the previously mentioned metals or alloys provided that the metals or alloys have sufficient conductive properties. Typically, the metal applied in the above-described metallization step is copper. The metal can be applied by conventional electroplating, seed electroplating, metal vapor deposition, or any other method providing a uniform metal layer as described above. The thickness of the metal layer is typically about 5 to 50 microns.

To enhance the adhesion of the metal layer to the dielectric coating prior to the metallization step, all surfaces can be treated with ion beam, electron beam, corona discharge or plasma bombardment, followed by application of an adhesion promoter layer to all surfaces. The adhesion promoter layer can have a thickness ranging from 50 to 5000 Angstroms, and typically is a metal or metal oxide selected from chromium, titanium, nickel, cobalt, cesium, iron, aluminum, copper, gold, tungsten and zinc, and alloys and oxides thereof.

Also, prior to application of the dielectric coating, the core surface may be pretreated or otherwise prepared for the application of the dielectric material. For example, cleaning, rinsing, and/or treatment with an adhesion promoter prior to application of the dielectric may be appropriate.

After metallization, a photosensitive layer (formed from a “photoresist” or “resist” composition) can be applied to the metal layer. Optionally, prior to application of the photosensitive layer the metallized substrate can be cleaned and pretreated; e.g., treated with an acid etchant to remove oxidized metal. The photosensitive layer can be a positive or negative photosensitive layer. The photosensitive layer typically has a thickness of about 2 to 50 microns and can be applied by any method known to those skilled in the photolithographic processing art. Additive or subtractive processing methods may be used to create the desired circuit patterns.

Suitable positive-acting photosensitive resins include any of those known to practitioners skilled in the art. Examples include dinitro-benzyl functional polymers. Such resins have a high degree of photosensitivity. In one example, the resinous photosensitive layer can be a composition comprising a dinitro-benzyl functional polymer, typically applied by spraying. Nitrobenzyl functional polymers are also suitable.

The photosensitive layer can also be an electrodepositable composition comprising a dinitrobenzyl functional polyurethane and an epoxy-amine polymer.

Negative-acting photoresists include liquid or dry-film type compositions. Liquid compositions may be applied by rolling application techniques, curtain application, or electrodeposition. Preferably, liquid photoresists are applied by electrodeposition, more preferably cationic electrodeposition. Electrodepositable compositions comprise an ionic, polymeric material, which may be cationic or anionic, and may be selected from polyesters, polyurethanes, acrylics, and polyepoxides.

After the photosensitive layer is applied, a photo-mask having a desired pattern may be placed over the photosensitive layer and the layered substrate exposed to a sufficient level of a suitable actinic radiation source. As used herein, the term “sufficient level of actinic radiation” refers to that level of radiation which polymerizes the monomers in the radiation-exposed areas in the case of negative-acting resists, or which depolymerizes the polymer or renders the polymer more soluble in the case of positive-acting resists. This results in a solubility differential between the radiation-exposed and radiation-shielded areas.

The photo-mask may be removed after exposure to the radiation source and the layered substrate developed using conventional developing solutions to remove more soluble portions of the photosensitive layer, and uncover selected areas of the underlying metal layer. The metal, which is uncovered during this step, may then be etched using metal etchants that convert the metal to water-soluble metal complexes. The soluble complexes may be removed by water spraying.

The photosensitive layer protects any metal under it during the etching step. The remaining photosensitive layer, which is impervious to the etchants, may then be removed by a chemical stripping process to provide a circuit pattern connected by the metallized vias formed as described above.

It should be understood that any of the processes of the present invention can include one or more additional steps without departing from the scope of the inventor. Likewise, the order in which the steps are performed may be changed as necessary, without departing from the scope of the invention.

After preparation of the circuit pattern on the substrate, one or more other circuit components may be attached in one or more subsequent steps to form a circuit assembly. Additional components can include one or more multi-layer circuit assemblies prepared by any of the processes described above, smaller scale components such as semiconductor chips, interposer layers, larger scale circuit cards or motherboards and active or passive components. Components may be attached using conventional adhesives, surface mount techniques, wire bonding or flip-chip techniques.

While the figures show one or more cavities in a single side of a substrate, it should be understood that the cavities can be formed on one or both sides of the substrate. The processing described above would be used to create the desired circuitry and electrical connections to connect the chips and/or other components to the package and ultimately to a circuit board that can support the chip package. In one example, chips could be wire-bonded to circuitry on the surface of the substrate.

In another example, chips could be flip-chip connected to circuitry within the cavity. In this case, electrical conductors could be routed from the surface of the substrate along the sidewalls of the cavity to the bottom of the cavity and/or chips could be connected to circuitry on the bottom of the substrate using vias that provide an electrical connection to the opposite side of the substrate.

The chip could be encapsulated using a dielectric material and then circuit trenches could be routed out, and conductors formed in the trenches to connect the circuitry on the package to circuitry on the chip. These chips could then be metalized and the electrical connections would be completed. The chip could also be flip-chip attached directly to a circuit board. Any combination of the connection techniques could also be used.

As used in this description, unless indicated to the contrary, the numerical parameters are approximations that may vary depending upon the desired properties sought to be obtained by the present invention. Thus each numerical parameter should at least be construed in light of the number of reported significant digits and by applying ordinary rounding techniques, or by taking typically manufacturing tolerances into account.

Also, it should be understood that any numerical range recited herein is intended to include all sub-ranges subsumed therein. For example, a range of “1 to 10” is intended to include all sub-ranges between and including the recited minimum value of 1 and the recited maximum value of 10, that is, having a minimum value equal to or greater than 1 and a maximum value of equal to or less than 10.

The assemblies of this invention provide both physical and electrical protection for the semiconductor device, guarding the device from physical or electrical damage. While the above examples show a cavity in a substrate having a uniform core thickness, the thickness of the core need not be uniform. FIG. 12 is a cross-sectional view of an alternative embodiment of a substrate 200 including a core 202 shaped to form a cavity 204 having a bottom 206 and sides 208 that extend from the periphery of the bottom. First and second layers 210 and 212 of an insulating material are positioned on opposite sides of the core. The substrate can include a plurality of electrical conductors or contact pads, illustrated as items 214, 216, 218 and 220. The contact pads (for example 214 and 220) can be mounted on a surface of, or embedded in, the first layer of insulating material, or in vias to form contact pads (for example 216 and 218) that are electrically connected to the core layer of the substrate. The arrangement of the contact pads can be chosen to accommodate various semiconductor devices mounted at least partially in the cavity. In. the example of FIG. 12, pads 214 and 220 extend to the edges of the cavity, and possibly beyond the edges of the cavity, and provide a means for connecting a device mounted in the cavity to another circuit. Openings can be included in the top layer of insulation to form blind vias that expose portions of the core and can include conductive material used to make electrical connections to the core (for example 216 and 218). One or more vias 222 can be provided in the substrate. Such vias can extend through the core and can be insulated, for example by a layer of dielectric material 224, from the core. The vias can be filled with a conductive material, or one or more conductors can pass through the vias, to provide an electrical connection between components or circuits positioned on opposite sides of the core. The circuit assemblies of this invention, when used to support a MOSFET, provide a low resistance electrical path to the backside of the silicon (drain) in a small form factor package. The assembly allows for connecting the active side of the silicon chip (source) to the bottom of the cavity and wiring the gate out to the edge of the can. The assemblies of this invention also facilitate double-sided cooling of the semicondlictor device. The thermal path is improved with the silicon backside soldered to the substrate.

While the invention has been described in terms of several examples, it will be apparent to those skilled in the art that various changes can be made to the described examples without departing from the scope of the invention as set forth in the following claims.

What is claimed is:

1. A substrate for an electronic device package comprising:
an electrically conductive core shaped to define a cavity for receiving an electronic device;
a first insulating layer on a first side of the core; and
a first contact positioned adjacent to a surface in the cavity.

2. The substrate of claim 1, wherein the first contact is positioned on the first insulating layer within the cavity.

3. The substrate of claim 1, wherein the first contact is electrically connected to the conductive core.

4. The substrate of claim 1, wherein the conductive core comprises one or more of:
untreated or galvanized steel, aluminum, gold, nickel, copper, magnesium or alloys of any of the foregoing metals.

5. The substrate of claim 1, wherein the conductive core comprises:
a metalized non-conductive material.

6. The substrate of claim 1, further comprising:
a second insulating layer on a second side of the core, wherein the first and second insulating layers conformally coat the conductive core.

7. The substrate of claim 6, wherein the first and second insulating layers are applied to the conductive core using electrodeposition.

8. The substrate of claim 6, further comprising:
a second core positioned adjacent to one of the first and second layers.

9. The substrate of claim 1, further comprising:
an opening in the core.

10. The substrate of claim 1, further comprising:
a circuitry layer positioned on the first insulating layer.

11. The substrate of claim 1, further comprising:
a first conductor electrically connected to the first contact and extending to a point outside of the cavity.

12. The substrate of claim 1, further comprising:
a via electrically connecting the first contact and the core.

13. A method of making a substrate for an electronic device package comprising:
providing an electrically conductive core;
deforming the core to define a cavity for receiving an electronic device;
applying a first insulating layer to a first side of the core; and
forming a first contact adjacent to a surface within the cavity.

14. The method of claim 13, wherein the first contact is positioned on the first insulating layer within the cavity.

15. The method of claim 13, wherein the first contact is electrically connected to the conductive core.

16. The method of claim 13, wherein the conductive core comprises one or more of:
untreated or galvanized steel, aluminum, gold, nickel, copper, magnesium or alloys of any of the foregoing metals,

17. The method of claim 13, wherein the conductive core comprises:
a metalized non-conductive material.

18. The method of claim 13, further comprising the step of:
applying a second insulating layer to a second side of the core, wherein the first and second insulating layers conformally coat the conductive core.

19. The method of claim 18, wherein the first and second insulating layers are applied to the conductive core using electrodeposition.

20. The method of claim 13, wherein the core is a portion of a sheet, and the method further comprises the steps of:
forming slots in the sheet adjacent to edges of the core; and
separating the core from the sheet.

21. The method of claim 13, wherein the core is deformed using one or more stamping, milling and etching processes.
